(19) United States
(12) Patent Application Publication
(10) Pub. No.: US 2019/0258100 A1
(43) Pub. Date: Aug. 22, 2019

(54) SUBSTRATE SUPPORT MEMBER

(71) Applicant: SAKAI DISPLAY PRODUCTS CORPORATION, Sakai-shi, Osaka (JP)

(72) Inventor: FUMITAKA OKA, Sakai-shi, Osaka (JP)

(73) Assignee: SAKAI DISPLAY PRODUCTS CORPORATION, Sakai-shi, Osaka (JP)

(21) Appl. No.: 16/333,592

(22) PCT Filed: Sep. 15, 2016
(86) PCT No.: PCT/JP2016/077279

§ 371 Date: Mar. 14, 2019

(51) Int. Cl. G02F 1/1345; G02F 1/1333; H05K 1/11

(52) U.S. Cl. CPC G02F 1/1345; G02F 1/133308; G02F 1/133528; G02F 2001/133331; H05K 1/118

(57) ABSTRACT

There is provided a substrate support member detachably mounted on a display panel for supporting a substrate electrically connected to the display panel via a film-like connection member. The substrate support member has a body part extending in a predetermined direction, a mounting part provided on a first end of the body part in the predetermined direction and sucked or adhered to one surface of the display panel, and a placement part on which the substrate is placed and provided on a second end of the body part in the predetermined direction.

### TECHNICAL FIELD

The present invention relates to a substrate support member for supporting a substrate to be connected to a display panel.

### BACKGROUND ART

In general, in a display panel module, a peripheral board such as a printed wire board (PWB) is electrically connected to a display panel via a film-like connection member such as System On Film (SOF), flexible printed circuit (FPC), or the like.

For example, Patent Document 1 discloses a display panel assembling apparatus including a support body that can selectively move between a support position where a peripheral board is supported from below and a non-support position where the peripheral board is not supported, in which when conveying a display panel module assembled by electrically connecting the peripheral board to a liquid crystal panel to the next process, the support body supports the peripheral board from below so as to prevent the peripheral board from hanging downward, whereby the display panel module can be conveyed to the next process without any trouble.

### PRIOR ART DOCUMENT

### Patent Document

Patent Document 1: JP 2006-293114 A

### SUMMARY OF THE INVENTION

### Problem to be Solved by the Invention

Meanwhile, there is a case where a display panel module in which a peripheral board is electrically connected to a display panel via a film-like connection member is distributed as a product as it is. In such a case, it is assumed that a worker conveys the display panel module without using any conveyance apparatus such as the assembling apparatus discussed in Patent Document 1. However, at the time of such conveyance, the peripheral board hangs downward by its own weight and the film-like connection member is pulled, thereby inducing occurrence of defects such as disconnection between the film-like connection member and the display panel, disconnection between the film-like connection member and the peripheral board, or breaking of wire in the film-like connection member.

In view of the foregoing circumstances, the object of the present invention is to provide a substrate support member that can prevent occurrence of defects due to hanging down of a peripheral board when a worker conveys a display panel module in which the peripheral board is electrically connected to a display panel via a film-like connection member.

### Means to Solve the Problem

A substrate support member according to an embodiment is a substrate support member for supporting a substrate electrically connected to a display panel via a film-like connection member, including a placement part on which the substrate is placed and a holding part for holding the placement part and configured to be detachably mounted to the display panel.

### Effects of the Invention

According to the present invention, when a worker conveys a display panel module in which a peripheral board is electrically connected to a display panel via a film-like connection member, it is possible to prevent occurrence of defects due to hanging down of the peripheral board.

### BRIEF DESCRIPTION OF THE DRAWINGS

FIG. 1 is a perspective view illustrating a substrate support member according to a first embodiment.

FIG. 2 is a perspective view illustrating a liquid crystal panel module to which the substrate support member according to the first embodiment is attached.

FIG. 3 is a cross-sectional view taken along line A-A of FIG. 2.

FIG. 4 is a partial cross-sectional view illustrating a liquid crystal panel module to which a substrate support member according to a second embodiment is attached.

FIG. 5 is a partial cross-sectional view illustrating another example of the substrate support member according to the second embodiment.

FIG. 6 is a partial cross-sectional view illustrating another example of the substrate support member according to the second embodiment.

FIG. 7 is a partial cross-sectional view illustrating a liquid crystal panel module to which a substrate support member according to a third embodiment is attached.

FIG. 8 is a partial cross-sectional view illustrating another example of the substrate support member according to the third embodiment.

FIG. 9 is a partial cross-sectional view illustrating a liquid crystal panel module to which a substrate support member according to a fourth embodiment is attached.

FIG. 10 is a partial cross-sectional view illustrating a liquid crystal panel module to which a substrate support member according to a fifth embodiment is attached.

### EMBODIMENT FOR CARRYING OUT THE INVENTION

Hereinafter, substrate support members according to embodiments of the present invention will be described in detail with reference to attached drawings, taking a case of being attached to a liquid crystal panel module as an example.

### First Embodiment

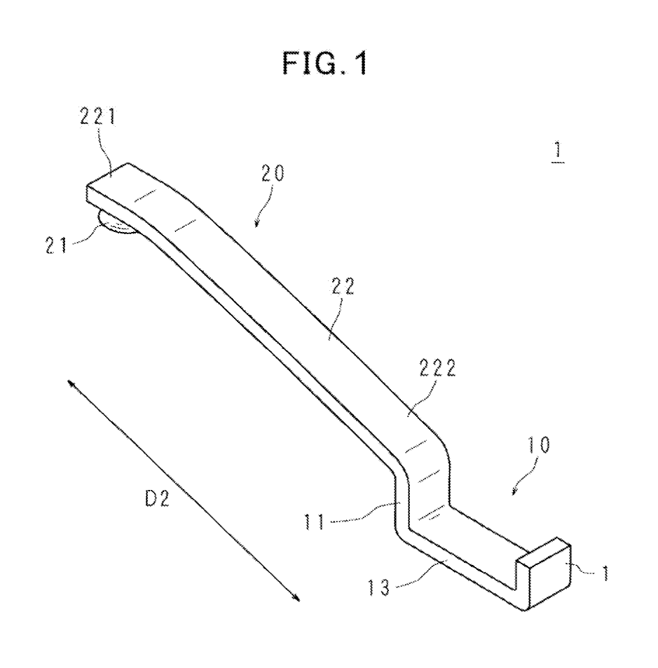

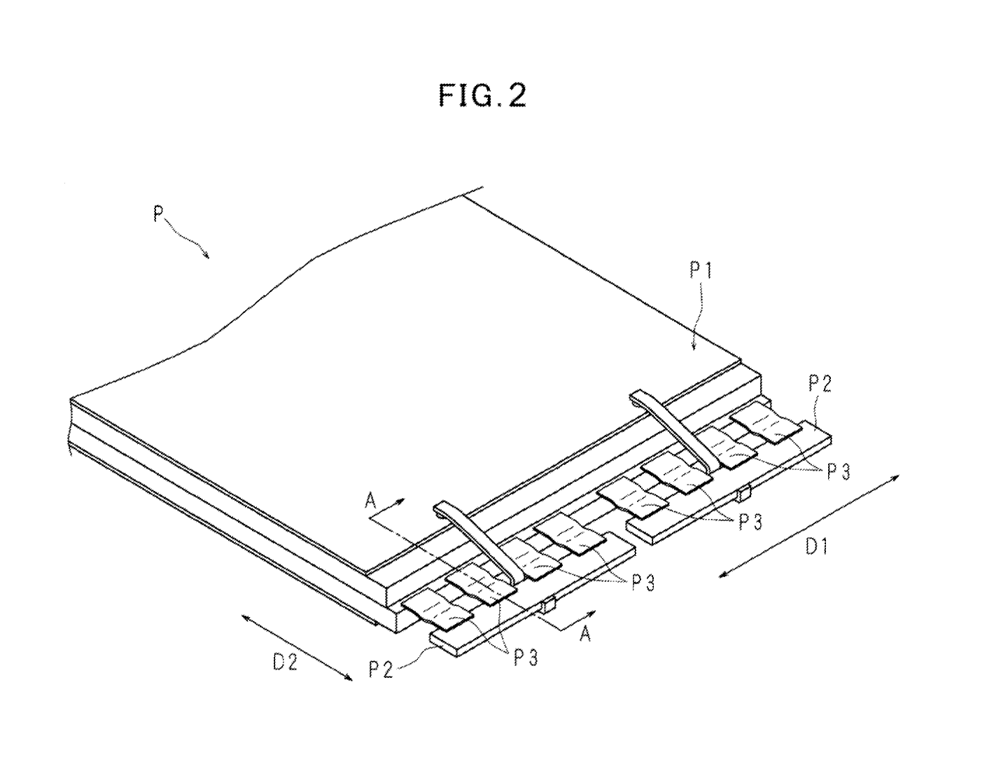

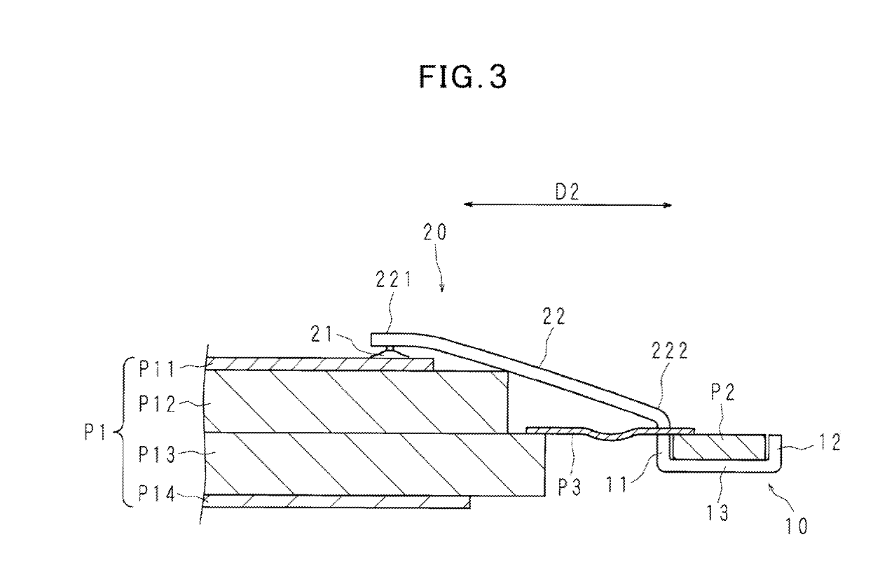

FIG. 1 is a perspective view illustrating substrate support member 1 according to a first embodiment. FIG. 2 is a perspective view illustrating a liquid crystal panel module to which the substrate support member 1 according to the first embodiment is attached. FIG. 3 is a cross-sectional view taken along line A-A of FIG. 2.

As illustrated in FIGS. 2 and 3, a liquid crystal panel module P has a liquid crystal panel P1, a substrate P2 for driving the liquid crystal panel P1, and film-like connection member P3 for electrically connecting the liquid crystal panel P1 and the substrate P2.

The liquid crystal panel P1 has a glass substrate P12 and a glass substrate P13 disposed so as to be opposed to each other with an interposed liquid crystal (not illustrated), a polarizing sheet P11 stretched and attached on an outer surface of the glass substrate P12, namely on a surface of the glass substrate P12 opposite to an inner surface facing the glass substrate P13, and a polarizing sheet P14 stretched and attached on an outer surface of the glass substrate P13, namely on a surface of the glass substrate P13 opposite to an inner surface facing the glass substrate P12.

The substrate P2 is a printed wire board (PWB) for driving the liquid crystal panel P1 and has a strip-like shape. The substrate P2 is electrically connected to the liquid crystal panel P1 via the connection member P3, in a state of being spaced apart from the liquid crystal panel P1. Hereinafter, the longitudinal direction of the substrate P2 is referred to as first direction D1.

The connection member P3 is, for example, a flexible film-like System On Film (SOF). One end of the connection member P3 is connected to the liquid crystal panel P1, more specifically connected to an end of the inner surface of the glass substrate P13, and the other end is connected to the substrate P2, more specifically connected to the substrate P2 at an end, which is closer to the liquid crystal panel P1 in a direction orthogonal to the first direction D1, of the substrate P2.

One or more (two in the present embodiment) substrates P2 are connected to the liquid crystal panel P1. One substrate P2 is connected to the liquid crystal panel P1 via one or more (four in the present embodiment) connection members P3. In the present embodiment, the substrate P2 is connected to the liquid crystal panel P1 via four connection members P3 arrayed in the first direction D1. Although FIG. 2 illustrates the substrates P2 connected to only one side out of four sides of the liquid crystal panel P1, the present embodiment is not limited to this illustration. The substrates P2 may be provided on two or more sides of the liquid crystal panel P1. Hereinafter, the side of the liquid crystal panel P1 to which the substrates P2 are connected is referred to as a substrate connection side. The substrates P2 are connected to the liquid crystal panel P1 so that the first direction D1 lies along the substrate connection side.

As illustrated in FIGS. 1 to 3, the substrate support member 1 is, for example, a plastic member elongated in one direction and supports the substrate P2. The substrate support member 1 includes placement part 10 on which the substrate P2 of the liquid crystal panel module P is placed and holding part 20 for holding the placement part 10 and configured to be detachably mounted to the liquid crystal panel P1.

The holding part 20 has a body part 22 extending in a longitudinal direction D2 (hereinafter, referred to as a second direction) of the substrate support member 1, and a mounting part 21. In the holding part 20, the mounting part 21 is provided on a first end 221 of the body part 22 in the second direction D2, and the body part 22 holds the placement part 10 on a second end 222 of the body part 22 in the second direction D2.

In the present embodiment, the mounting part 21 is a suction cup to be sucked to one surface of the liquid crystal panel P1. If necessary, a worker can attach or detach the substrate support member 1 to or from the liquid crystal panel module P by attaching or detaching the mounting part 21 to or from the liquid crystal panel P1. For example, as illustrated in FIG. 2, the body part 22 of the holding part 20 is disposed between two neighboring connection members P3 in a state where the substrate support member 1 (the holding part 20) is mounted on the liquid crystal panel P1.

The placement part 10 has a rectangular flat plate 13 on which the substrate P2 is placed, and restriction parts 11 and 12 for restricting the movement of the substrate P2 placed on the placement part 10 (the flat plate 13). The restriction part 11 is a protrusion standing perpendicularly from the flat plate 13 at an end, which is adjacent to the holding part 20 in the second direction D2, of the flat plate 13. The restriction part 11 has a distal end connected to the holding part 20. The restriction part 11 restricts the movement of the substrate P2 mounted on the flat plate 13 toward the holding part 20. The restriction part 12 is a protrusion standing perpendicularly from the flat plate 13 at an end, which is farther from the holding part 20 in the second direction, of the flat plate 13. The restriction part 12 restricts the movement of the substrate P2 mounted on the flat plate 13 away from the holding part 20.

The placement part 10 is not limited to the above-mentioned configuration. For example, the placement part 10 may have a configuration not including the restriction part 12. In the case of omitting the restriction part 12, the flat plate 13 may be configured to have a function of preventing slippage of the substrate P2.

As illustrated in FIG. 3, in the state where the substrate support member 1 is attached to the liquid crystal panel P1, the mounting part 21 is sucked to the polarizing sheet P11 of the liquid crystal panel P1 and the body part 22 is partly in contact with an end of the liquid crystal panel P1. By bringing the body part 22 into partly contact with the end of the liquid crystal panel P1, it is possible to support the weight of the substrate P2 by the end of the liquid crystal panel P1 in addition to the portion where the mounting part 21 is sucked. Thus, the position of the placement part 10 on which the substrate P2 is mounted can be prevented from being excessively lowered.

For example, when a worker conveys the liquid crystal panel module P in the state where the substrate support member 1 is attached to the liquid crystal panel P1, it is possible to prevent in advance the substrate P2 from hanging downward due to its own weight and being pulled in a direction away from the liquid crystal panel P1. Therefore, when the liquid crystal panel module P is conveyed, the substrate support member 1 according to the present embodiment can prevent occurrence of defects, such as disconnection between the connection member P3 and the liquid crystal panel P1, disconnection between the connection member P3 and the substrate P2, or breaking of wire in the connection member P3.

Further, in the substrate support member 1, as mentioned above, since the body part 22 of the holding part 20 is disposed between two neighboring connection members P3, it is unnecessary to secure a specific space where the substrate support member 1 is disposed.

Further, the configuration of the substrate support member 1 according to the present embodiment is not limited to the above description. For example, the mounting part 21 may be provided at a plurality of positions on the body part 22.

### Second Embodiment

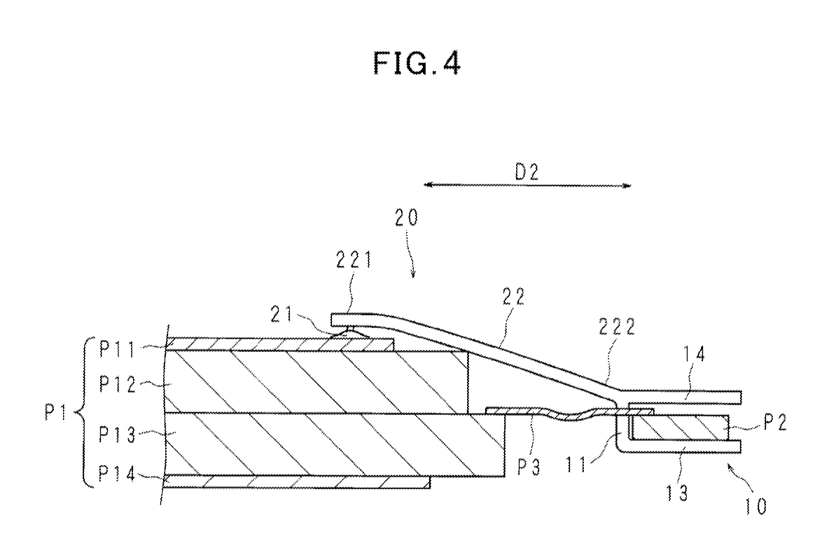

FIG. 4 is a partial cross-sectional view illustrating liquid crystal panel module P to which substrate support member 1 according to a second embodiment is attached. Similar to the first embodiment, the substrate support member 1 includes placement part 10 and holding part 20.

The placement part 10 has a rectangular flat plate 13 on which the substrate P2 is placed, and a restriction part 11 for restricting the movement of the substrate P2 placed on the placement part 10 (the flat plate 13). The restriction part 11 is provided so as to protrude perpendicularly from the flat plate 13 at an end, which is adjacent to the holding part 20 in the second direction D2, of the flat plate 13. The restriction part 11 has a distal end connected to the holding part 20. The restriction part 11 restricts the movement of the substrate P2 mounted on the flat plate 13 toward the holding part 20.

Further, the placement part 10 has opposing plate 14 opposing to a surface (hereinafter, referred to as a placement surface) of the flat plate 13 on which the substrate P2 is to be placed. The opposing plate 14 is continuously formed with the distal end of the restriction part 11, and has a shape substantially the same as the flat plate 13. More specifically, respective ends (ends adjacent to the holding part 20 in the second direction D2) of the flat plate 13 and the opposing plate 14 are continuously formed with the restriction part 11.

Similar to the first embodiment, the holding part 20 has a body part 22 extending in the second direction D2 and a mounting part 21. For example, the body part 22 has a rod-like shape or a flat plate-like shape. The mounting part 21 is provided on a first end 221 of the body part 22 in the second direction D2, and the body part 22 holds the placement part 10 on a second end 222 of the body part 22 in the second direction D2. The mounting part 21 is, for example, a suction cup.

On the other hand, as illustrated in FIG. 4, the substrate support member 1 according to the second embodiment does not have a restriction part (restriction part 12) provided at an end, which is farther from the holding part 20 in the second direction D2, of the flat plate 13. Accordingly, a worker can place the substrate P2 on the placement part 10 from the end, which is farther from the holding part 20 in the second direction D2, of the placement part 10. In the second embodiment, the upper surface of the substrate P2 is covered by the opposing plate 14 in a state of being mounted on the flat plate 13. Thus, the substrate P2 can be prevented from being lifted upward and the connection member P3 can be prevented from warping back due to vibrations generated when the liquid crystal panel module P is conveyed. Consequently, defects such as breaking of wire accompanying with it can be prevented from occurring.

Further, similar to the first embodiment, the substrate support member 1 according to the second embodiment can prevent the substrate P2 from hanging downward due to its own weight and being pulled in a direction away from the liquid crystal panel P1 when the liquid crystal panel module P is conveyed. Further, when the liquid crystal panel module P is conveyed, the substrate support member 1 according to the present embodiment can prevent occurrence of defects, such as disconnection between the connection member P3 and the liquid crystal panel P1, disconnection between the connection member P3 and the substrate P2, or breaking of wire in the connection member P3.

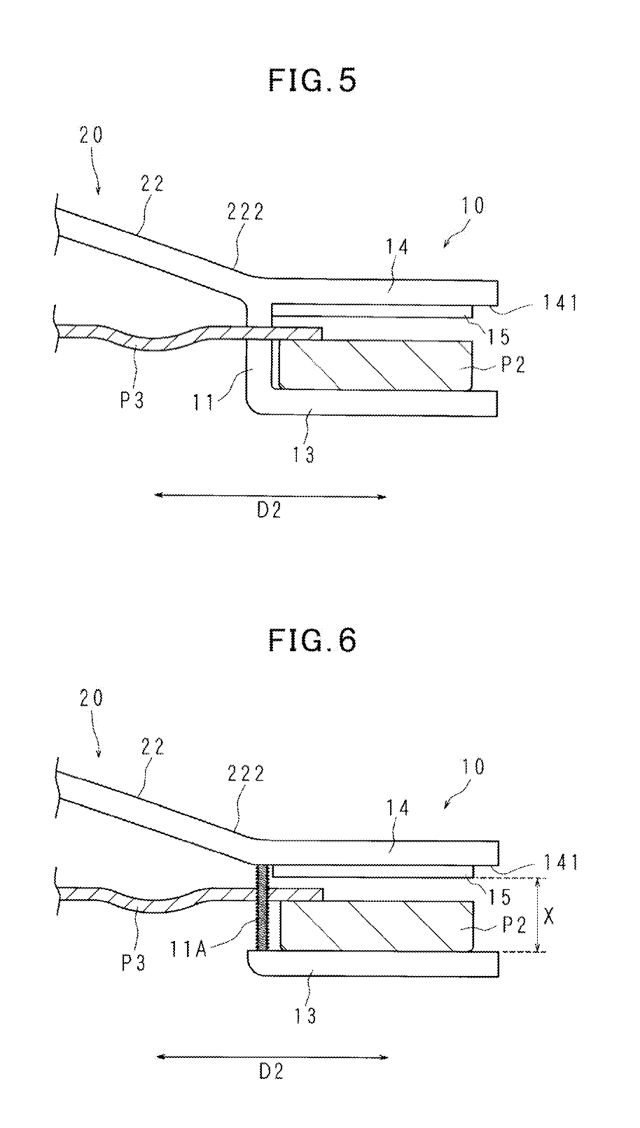

FIG. 5 is a partial cross-sectional view illustrating another example of the substrate support member 1 according to the second embodiment. In the substrate support member 1 illustrated in FIG. 5, the opposing plate 14 of the placement part 10 has a cushion part 15 (second cushion part). The cushion part 15 is provided on inner surface 141 of the opposing plate 14 facing the flat plate 13. The cushion part 15 is made of, for example, urethane, rubber or the like.

By providing the cushion part 15 on the inner surface 141 of the opposing plate 14 as described above, even when the substrate P2 is lifted upward and collides with the opposing plate 14 due to vibrations generated when the liquid crystal panel module P is conveyed, occurrence of defects in the substrate P2 can be prevented because the cushion part 15 absorbs the shock.

The cushion part 15 may be provided on the placement surface of the flat plate 13, or may be provided on both the placement surface of the flat plate 13 and the inner surface 141 of the opposing plate 14.

FIG. 6 is a partial cross-sectional view illustrating another example of the substrate support member 1 according to the second embodiment.

In the substrate support member 1 illustrated in FIG. 6, gap X between the flat plate 13 and the opposing plate 14 is variable. For example, according to the example illustrated in FIG. 6, a male thread 11A is provided instead of the restriction part 11. The male thread 11A is provided so as to protrude perpendicularly from the flat plate 13 at an end, which is adjacent to the holding part 20 in the second direction D2, of the flat plate 13. Further, a female thread (not illustrated) is recessed so as to correspond to the male thread 11A at an end, which is adjacent to the holding part 20 in the second direction D2, of the opposing plate 14. By screwing the male thread 11A into the female thread, the flat plate 13 and the opposing plate 14 are connected together. The male thread 11A restricts the movement of the substrate P2 mounted on the flat plate 13 toward the holding part 20.

Further, by rotating the male thread 11A, the gap X between the flat plate 13 and the opposing plate 14 can be adjusted. Thus, the gap X between the flat plate 13 and the opposing plate 14 can be easily changed to an appropriate gap according to the thickness of the substrate P2 and the connection member P3. The gap X between the flat plate 13 and the opposing plate 14 is preferably set to be substantially equal to a sum of the thickness of substrate P2 and the thickness of connection member P3. By setting the gap X between the flat plate 13 and the opposing plate 14 to be substantially equal to the sum of the thickness of substrate P2 and the thickness of connection member P3, it is possible to surely prevent occurrence of defects such as warping back of the connection member P3 due to lifting up of the substrate P2, breaking of wire caused thereby, and collision of the substrate P2 with the opposing plate 14.

### Third Embodiment

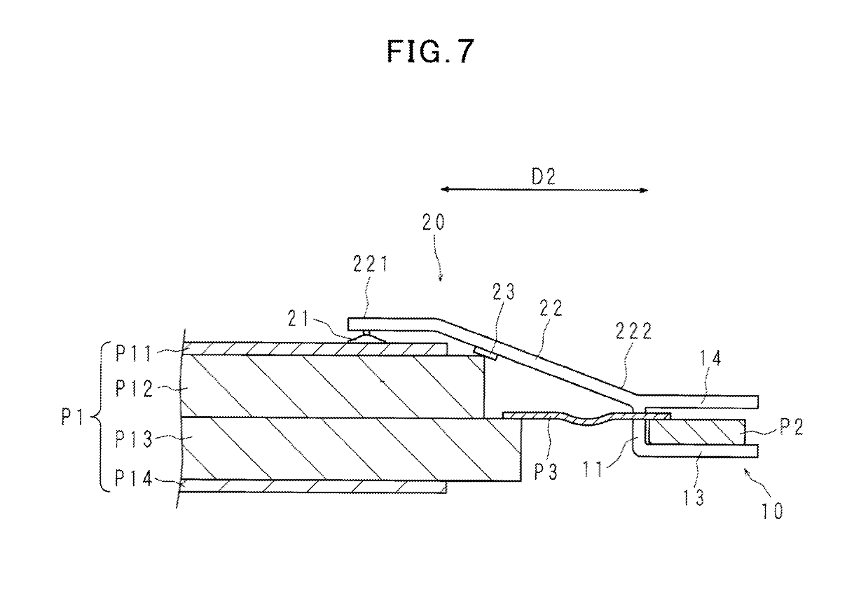

FIG. 7 is a partial cross-sectional view illustrating liquid crystal panel module P to which substrate support member 1 according to a third embodiment is attached. Similar to the first embodiment, the substrate support member 1 includes placement part 10 and holding part 20.

Similar to the first embodiment, the holding part 20 has a body part 22 extending in the second direction D2 and a mounting part 21. For example, the body part 22 has a rod-like shape or a flat plate-like shape. The mounting part 21 is provided on a first end 221 of the body part 22 in the second direction D2, and the body part 22 holds the placement part 10 on a second end 222 of the body part 22 in the second direction D2. The mounting part 21 is, for example, a suction cup.

The configuration of the placement part 10 according to the third embodiment is identical to that of the placement part according to the second embodiment. More specifically, the placement part 10 has a rectangular flat plate 13 on which the substrate P2 is placed, a restriction part 11 for restricting the movement of the substrate P2 mounted on the placement part 10 (the flat plate 13), and an opposing plate 14 facing the placement surface of the flat plate 13. The placement part 10 according to the third embodiment may have the same configuration as the placement part 10 according to the first embodiment.

The substrate support member 1 according to the third embodiment has cushion part 23 (a first cushion part) at a portion where the body part 22 is in contact with an end of the liquid crystal panel P1. The cushion part 23 is made of, for example, urethane, rubber or the like.

As illustrated in FIG. 7, in a state where the substrate support member 1 is attached to the liquid crystal panel P1, the mounting part 21 is sucked to the polarizing sheet P11 of the liquid crystal panel P1 and the cushion part 23 of the body part 22 is in contact with the end of the liquid crystal panel P1. By bringing the cushion part 23 of the body part 22 into contact with the end of the liquid crystal panel P1, it is possible to support the weight of the substrate P2 by the end of the liquid crystal panel P1 in addition to the portion where the mounting part 21 is sucked.

Further, since the substrate support member 1 according to the third embodiment has the cushion part 23, it is possible to prevent the end of the liquid crystal panel P1 from being scratched by rubbing against the body part 22 of the substrate support member 1, even if the liquid crystal panel module P vibrates, for example, at the time of conveyance of the liquid crystal panel module P.

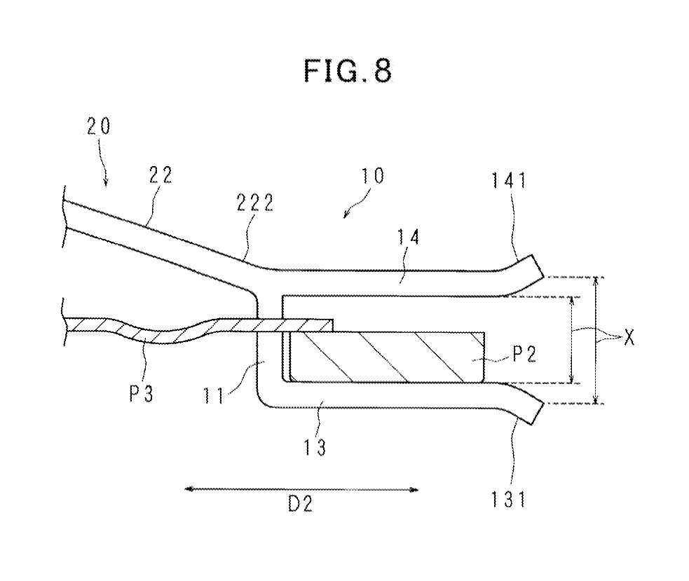

FIG. 8 is a partial cross-sectional view illustrating another example of the substrate support member 1 according to the third embodiment.

As illustrated in FIG. 8, an end, which is farther from the holding part 20 in the second direction D2, of the placement part 10 is formed into a tapered shape. More specifically, at an end 131, which is farther from the holding part 20 in the second direction D2, of the flat plate 13 and an end 141, which is farther from the holding part 20 in the second direction D2, of the opposing plate 14, the gap X between the flat plate 13 and the opposing plate 14 is configured so as to become larger as the flat plate 13 and the opposing plate 14 separate away from the holding part 20, more specifically, so as to become larger as the flat plate 13 and the opposing plate 14 separate away from the liquid crystal panel P1 on which the holding part 20 is mounted.

Since the end, which is farther from the holding part 20 in the second direction D2, of the placement part 10 has the tapered shape as mentioned above, the work for placing the substrate P2 on the placement part 10 from this end becomes easy.

### Fourth Embodiment

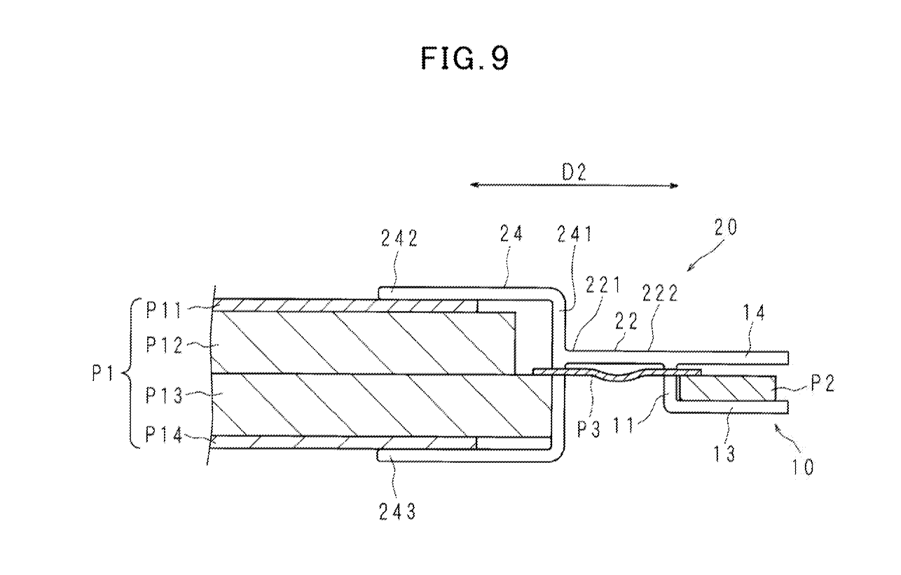

FIG. 9 is a partial cross-sectional view illustrating liquid crystal panel module P to which substrate support member 1 according to a fourth embodiment is attached. Similar to the first embodiment, the substrate support member 1 includes placement part 10 and holding part 20.

The configuration of the placement part 10 according to the fourth embodiment is identical to that of the placement part according to the second embodiment. More specifically, the placement part 10 has a rectangular flat plate 13 on which the substrate P2 is placed, a restriction part 11 for restricting the movement of the substrate P2 mounted on the placement part 10 (the flat plate 13), and an opposing plate 14 facing the placement surface of the flat plate 13. The placement part 10 according to the fourth embodiment may have the same configuration as the placement part 10 according to the first embodiment.

Similar to the first embodiment, the holding part 20 has body part 22 extending in the second direction D2 and mounting part 24. In the present embodiment, the mounting part 24 is a clip that clamps the liquid crystal panel P1 from both surfaces (one surface of polarizing sheet P11 and one surface of the polarizing sheet P14) in the thickness direction thereof. The substrate support member 1 can be attached to or detached from the liquid crystal panel module P by attaching or detaching the mounting part 24 to or form the liquid crystal panel P1.

In the present embodiment, the mounting part 24 has a side plate 241 to be opposed to an end face of the liquid crystal panel P1 on the substrate connection side in the state of being attached to the liquid crystal panel P1, and abutment plates 242 and 243 provided so as to extend in the second direction D2 toward the liquid crystal panel P1 from both edges of the side plate 241 in the thickness direction of the liquid crystal panel P1. The abutment plates 242 and 243 are disposed so as to be opposed to each other in the thickness direction of the liquid crystal panel P1. In the state where the mounting part 24 is attached to the liquid crystal panel P1, the abutment plate 242 is in contact with an outer surface of the polarizing sheet P11 and the abutment plate 243 is in contact with an outer surface of the polarizing sheet P14. For example, a first end 221 of the body part 22 is continuously formed with a central portion of the side plate 241 in the thickness direction of the liquid crystal panel P1.

The substrate support member 1 according to the present embodiment enables a worker to attach the substrate support member 1 to the liquid crystal panel P1 by performing a simple operation for fitting the mounting part 24 to the liquid crystal panel P1 and clamping the end of the liquid crystal panel P1 on the substrate connection side.

### Fifth Embodiment

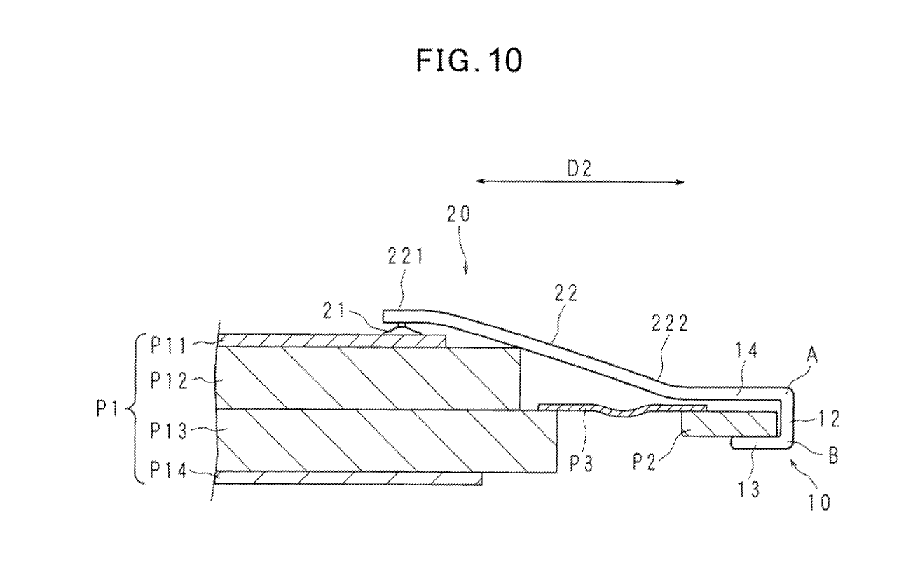

FIG. 10 is a partial cross-sectional view illustrating liquid crystal panel module P to which substrate support member 1 according to a fifth embodiment is attached. Similar to the first embodiment, the substrate support member 1 includes placement part 10 and holding part 20.

The placement part 10 according to the present embodiment has a hook shape in a cross-sectional view, which is bent at two points of first bending point A and second bending point B. A tip end region of the placement part 10, more specifically, a region extending from the second bending point B to the tip end thereof, corresponds to the flat plate 13. A region of the placement part 10 extending from the first bending point A to the second bending point B corresponds to the restriction part 12 to be disposed at the end which is farther from the holding part 20 in the second direction D2. A region extending from a connection point where the placement part 10 is connected to the holding part 20 to the first bending point A corresponds to the opposing plate 14. For example, the size of the opposing plate 14 in the second direction D2 is larger than the size of the flat plate 13. However, the size of the opposing plate 14 in a direction intersectional to the second direction D2, more specifically in the first direction D1, is substantially equal to the size of the flat plate 13.

The substrate support member 1 according to the present embodiment enables a worker to place the substrate P2 on the placement part 10 with an easy work for hooking the substrate P2 on the tip end region of the placement part 10 having the hook shape in a cross-sectional view.

In the above description, the case where the substrate support member 1 is attached to the liquid crystal panel module P has been taken as an example. However, an object to which the substrate support member 1 is attached is not limited to the liquid crystal panel module P. It is needless to say that the substrate support member 1 is applicable to other display panels, such as an organic electro luminescence (EL) display, a plasma display and the like.

### REFERENCE SIGNS LIST

1 substrate support member
10 placement part
11,12 restriction part
13 flat plate
14 opposing plate
15 cushion part
20 holding part
21, 24 mounting part
22 body part
23 cushion part
221 first end
222 second end
P1 liquid crystal panel
P2 substrate
P3 connection member

1. A substrate support member detachably mounted on a display panel for supporting a substrate electrically connected to the display panel via a film-like connection member, comprising:
a body part extending in a predetermined direction;
a mounting part provided on a first end of the body part in the predetermined direction and sucked or adhered to one surface of the display panel; and
a placement part on which the substrate is placed and provided on a second end of the body part in the predetermined direction.

2-3. (canceled)

4. The substrate support member according to claim 1, wherein
the substrate is connected to the display panel via a plurality of connection members arrayed in a predetermined alignment direction, and
the substrate support member is mounted on the display panel so that the predetermined direction is substantially orthogonal to the alignment direction, and
when mounted on the display panel, the body part is disposed between two neighboring connection members.

5. The substrate support member according to claim 4, wherein when mounted on the display panel, the body part partly comes into contact with an end of the display panel.

6. The substrate support member according to claim 5, wherein the body part has a first cushion part provided at a portion where the body part is in contact with the display panel.

7. The substrate support member according to claim 1, wherein the placement part has a restriction part for restricting movement of the substrate mounted on the placement part.

8. The substrate support member according to claim 1, wherein
the placement part has
a flat plate on which the substrate is placed, and
an opposing plate facing a surface of the flat plate on which the substrate is to be placed.

9. The substrate support member according to claim 8, wherein the flat plate and/or the opposing plate has a second cushion part on a surface facing the opposing plate or the flat plate.

10. The substrate support member according to claim 8, wherein a gap between the flat plate and the opposing plate is substantially equal to a sum of the thickness of the substrate and the thickness of the connection member.

11. The substrate support member according to claim 8, wherein the gap between the flat plate and the opposing plate is variable.

12. The substrate support member according to claim 8, wherein the placement part is configured in such a manner that a gap between the flat plate and the opposing plate becomes larger as the flat plate and the opposing plate separate away from the display panel at an end, which is farther from the display panel, of the placement part.
